(19) United States
(12) Patent Application Publication
(10) Pub. No.: US 2025/0230574 A1
(43) Pub. Date: Jul. 17, 2025

(54) METHOD AND APPARATUS FOR PRODUCING SILICON SINGLE CRYSTAL AND METHOD FOR PRODUCING SILICON WAFER

(71) Applicant: SUMCO Corporation, Tokyo (JP)

(72) Inventors: Yasunobu SHIMIZU, Tokyo (JP); Ippei SHIMOZAKI, Tokyo (JP); Keiichi TAKANASHI, Tokyo (JP); Ken HAMADA, Tokyo (JP)

(73) Assignee: SUMCO Corporation, Tokyo (JP)

(21) Appl. No.: 18/853,648

(22) PCT Filed: Feb. 1, 2023
(86) PCT No.: PCT/JP2023/003164

§ 371 Date: Oct. 2, 2024

(30) Foreign Application Priority Data
Apr. 8, 2022 (JP) 2022-064365

(51) Int. Cl. C30B 15/26; C30B 15/10; C30B 29/06

(52) U.S. Cl. CPC C30B 15/26; C30B 15/10; C30B 29/06

(57) ABSTRACT

A method and apparatus for manufacturing a silicon single crystal by pulling a silicon single crystal from a silicon melt in a quartz crucible, wherein images including a mirror image of the quartz crucible reflected on a melt surface of the silicon melt are acquired at predetermined time intervals, and deformation or eccentricity of the quartz crucible is evaluated from temporal changes of the position of the mirror image of the quartz crucible captured in a plurality of images that are acquired while the quartz crucible rotates at least once.

### TECHNICAL FIELD

The present invention relates to a method and apparatus for manufacturing a silicon single crystal according to a Czochralski method (CZ method) and, more particularly, to an evaluation method for deformation or eccentricity of a quartz crucible. The present invention also relates to a method for manufacturing a silicon wafer using such a silicon single crystal.

### BACKGROUND ART

Many silicon wafers used for a substrate material of semiconductor devices are produced by processing a silicon single crystal ingot grown by a CZ method. In the CZ method, a polycrystalline silicon material is melted in a quartz crucible to produce a silicon melt, and then a seed crystal is dipped into the produced silicon melt and is then gradually lifted while the quartz crucible and the seed crystal are being rotated, whereby a large single crystal is grown at the lower end of the seed crystal. Using the CZ method can increase the yield of a large-diameter silicon single crystal.

A quartz crucible is a silica glass container that holds a silicon melt. Therefore, quartz crucibles are required to have high durability so that they are not deformed at a high temperature equal to or higher than the melting point of silicon and can withstand long-term use. If the quartz crucible is deformed during a crystal pulling process, the shape and quality of the silicon single crystal may change, and in the worst case, the wall of the crucible may come into contact with in-furnace structures, leading to an accident. To prevent such trouble, it is preferable to monitor the deformation of the quartz crucible. For example, Patent Document 1 describes a method for detecting the deformation of a crucible from a sudden change in the height of the melt surface associated with a change in the volume of the crucible.

### BACKGROUND ART LITERATURE

### Patent Literature

Patent Literature 1: Japanese Patent Laid-open Publication No. 2021-109826A

### SUMMARY OF THE INVENTION

### Problems to Be Solved by the Invention

In a raw material melting process in which a polycrystalline silicon raw material in the quartz crucible is heated and melted, a large thermal load is applied to the quartz crucible due to radiant heat from the heater, which tends to cause the upper end of the quartz crucible to collapse If such deformation of the crucible occurs, the inward. crucible and a heat-shield body come into contact during the single crystal pulling process, making it impossible to continue the process. Furthermore, even if the crystal pulling process can be continued, the convection of the silicon melt in the quartz crucible changes, which may cause an oxygen abnormality in the silicon single crystal. Therefore, it is essential to check for the crucible deformation during the crystal pulling process, especially during a raw material melting process where the crucible deformation is likely to occur. However, at present, the only way to make an assessment is to visually observe the inside of the furnace by an operator, and there is no way to quantitatively evaluate the amount of the crucible deformation.

The present invention has been made in view of the above-mentioned problem, and an object thereof is to provide a method and apparatus for manufacturing a silicon single crystal, capable of quantitatively evaluating the presence/absence or magnitude of deformation or eccentricity of a quartz crucible and a method for manufacturing a silicon wafer using such a silicon single crystal.

### Means for Solving the Problems

To solve the above problem, a silicon single crystal manufacturing method according to the present invention is a method for manufacturing a silicon single crystal by pulling a silicon single crystal from a silicon melt in a quartz crucible, the method including: acquiring images including a mirror image of the quartz crucible reflected on a melt surface of the silicon melt at predetermined time intervals; and evaluating deformation or eccentricity of the quartz crucible from a temporal change in the position of the mirror image of the quartz crucible captured in a plurality of images acquired while the quartz crucible rotates at least once. According to the present invention, it is possible to objectively grasp a change in shape due to deformation or eccentricity of the quartz crucible, thereby preventing an accident and deterioration in the quality of the silicon single crystal due to deformation of the quartz crucible.

The silicon single crystal manufacturing method according to the present invention preferably detects the position of an upper end of the quartz crucible from the mirror image of the quartz crucible and calculates an amount of deformation or eccentricity of the upper end from a temporal change in the position of the upper end. This makes it possible to objectively evaluate the degree of deformation of the upper end of the quartz crucible and the degree of eccentricity of the crucible. It is also possible to evaluate the deformation of only the upper end of the quartz crucible, which does not affect the height fluctuation of the melt surface.

The silicon single crystal manufacturing method according to the present invention preferably detects the upper end of the quartz crucible from the differential value of luminance in the vertical direction of pixels in the image. This makes it possible to objectively evaluate the degree of deformation and eccentricity of the upper end of the quartz crucible.

The silicon single crystal manufacturing method according to the present invention preferably includes: setting a detection line for the position of the upper end in a plane including the optical axis of a camera for photographing the image; and calculating a charge amount of the quartz crucible from the temporal change in the position of the mirror image of the quartz crucible on the set detection line. This makes it possible to easily calculate the change amount of the quartz crucible.

The silicon single crystal manufacturing method according to the present invention preferably calculates a change amount of the quartz crucible based on the plurality of images acquired during a period from the start of a raw material melting step of melting a silicon raw material in the quartz crucible until the start of a dipping step of dipping a seed crystal into the silicon melt. A large heat load is applied to the quartz crucible during the raw material melting process, so that the upper end of the quartz crucible tends to fall inward. By calculating the change amount of the quartz crucible during the raw material melting process, it is possible to prevent an accident and a reduction in single crystal yield due to deformation of the quartz crucible.

Further, a silicon single crystal manufacturing apparatus according to the present invention includes: a quartz crucible that holds a silicon melt; a heater that is provided so as to surround the quartz crucible and heats the silicon melt; a crucible driving unit that rotates the quartz crucible and drives the same up and down; a crystal pulling unit that pulls up a silicon single crystal from the silicon melt; a heat-shield body that is disposed above the quartz crucible so as to surround the silicon single crystal pulled up from the silicon melt; a camera that photographs a melt surface of the silicon melt that can be seen through an opening of the heat-shield body from diagonally above; and an image processor that processes images photographed by the camera. The camera acquires images including a mirror image of the quartz crucible reflected on the melt surface at predetermined time intervals, and the image processor evaluates deformation or eccentricity of the quartz crucible from a temporal change in the position of the mirror image of the quartz crucible captured in a plurality of images acquired while the quartz crucible rotates at least once. According to the present invention, it is possible to objectively grasp a change in shape due to deformation and eccentricity of the quartz crucible, thereby preventing an accident and deterioration in the quality of the silicon single crystal due to deformation of the quartz crucible.

In the present invention, the image processor preferably detects a position of an upper end of the quartz crucible from the mirror image of the quartz crucible and calculates an amount of deformation or eccentricity of the upper end from a temporal change in the position of the upper end. This makes it possible to objectively evaluate the degree of deformation of the upper end of the quartz crucible and the degree of eccentricity of the crucible.

In the present invention, the image processor preferably detects the upper end of the quartz crucible from the differential value of luminance in the vertical direction of pixels in the image. This makes it possible to objectively evaluate the degree of deformation and eccentricity of the upper end of the quartz crucible.

In the present invention, the image processor preferably sets a detection line for the position of the upper end in a plane including the optical axis of the camera for photographing the image and calculates a charge amount of the quartz crucible from the temporal change in the position of the mirror image of the quartz crucible on the set detection line. This makes it possible to easily calculate the change amount of the quartz crucible.

In the present invention, the image processor preferably calculates a change amount of the quartz crucible based on the plurality of images acquired during a period from the start of a raw material melting step of melting a silicon raw material in the quartz crucible until the start of a dipping step of dipping a seed crystal into the silicon melt. By calculating the change amount of the quartz crucible during the raw material melting process, it is possible to prevent an accident and a reduction in single crystal yield due to deformation of the quartz crucible.

A silicon wafer manufacturing method according to the present invention includes producing a silicon wafer by processing a silicon single crystal manufactured by the above-described silicon single crystal manufacturing method according to the present invention. According to the present invention, the manufacturing yield of a silicon wafer can be increased.

### Effects of the Invention

According to the present invention, it is possible to provide a method and apparatus for manufacturing a silicon single crystal, capable of quantitatively evaluating the presence/absence or magnitude of deformation or eccentricity of a quartz crucible and a method for manufacturing a silicon wafer using such a silicon single crystal.

### BRIEF DESCRIPTION OF THE DRAWINGS

FIG. 1 is an explanatory view of a method for manufacturing a silicon single crystal according to an embodiment of the present invention, which is a schematic cross-sectional view illustrating the configuration of a single crystal manufacturing apparatus.

FIG. 2 is a flowchart illustrating a manufacturing process of the silicon single crystal according to the present embodiment.

FIG. 3 is a schematic cross-sectional view illustrating the shape of a silicon single crystal ingot.

FIG. 4 is a view for explaining a method of detecting deformation of the quartz crucible, which is a conceptual view of a CZ pulling furnace in the raw material melting step.

FIGS. 5A and 5B are schematic views of images of the melt surface of the silicon melt in the quartz crucible photographed by the camera, FIG. 5A illustrates an image of the upper end of the quartz crucible when the quartz crucible is not deformed, and FIG. 5B illustrates an image of the upper end of the quartz crucible when the quartz crucible is deformed.

FIG. 6 is an explanatory view of how to determine the position of the mirror image edge of the quartz crucible.

FIG. 7 is a graph illustrating an example of the measurement results of the position of the mirror image edge at the upper end of the quartz crucible 11 rotating at a constant speed.

### MODE FOR CARRYING OUT THE INVENTION

Hereinafter, a preferred embodiment of the present invention will be described in detail with reference to the accompanying drawings.

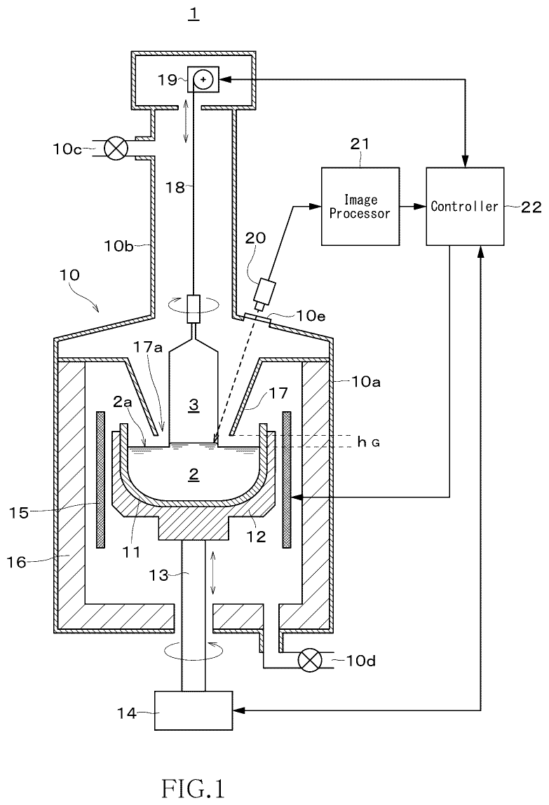

FIG. 1 is an explanatory view of a method for manufacturing a silicon single crystal according to an embodiment of the present invention, which is a schematic cross-sectional view illustrating the configuration of a single crystal manufacturing apparatus.

As illustrated in FIG. 1, a single crystal manufacturing apparatus 1 includes a water-cooled chamber 10, a quartz crucible 11 that holds a silicon melt 2 in the chamber 10, a graphite crucible 12 that holds the quartz crucible 11, a rotary shaft 13 that supports the graphite crucible 12, a crucible drive mechanism 14 that rotates the quartz crucible 11 and drives the same up and down through the rotary shaft 13 and graphite crucible 12, a heater 15 disposed around the graphite crucible 12, a heat insulator 16 disposed along the inner surface of the chamber 10 at the outside of the heater 15, a heat-shield body 17 disposed above the quartz crucible 11, a pulling wire 18 disposed above the quartz crucible 11 so as to be coaxial with the rotary shaft 13, a crystal pulling mechanism 19 disposed above the chamber 10, a camera 20 for photographing the inside of the chamber 10, an image processor 21 for processing images photographed by the camera 20, and a controller 22 that controls the above components of the single crystal manufacturing apparatus 1.

The chamber 10 is composed of a main chamber 10a and an elongated cylindrical pull chamber 10b connected to an upper opening of the main chamber 10a. The quartz crucible 11, graphite crucible 12, heater 15, and heat-shield body 17 are provided inside the main chamber 10a. The pull chamber 10b is provided with a gas inlet 10c for introducing an inert gas (purge gas) such as argon gas or dopant gas into the chamber 10, and the lower part of the main chamber 10a is provided with a gas exhaust port 10d for discharging atmospheric gas inside the chamber 10. Furthermore, a viewing window 10e is provided at the upper part of the main chamber 10a, through which the growth status of a silicon single crystal 3 can be observed.

The quartz crucible 11 is a silica glass container having a cylindrical side wall and a curved bottom. The graphite crucible 12 is held in close contact with the outer surface of the quartz crucible 11 so as to wrap around the quartz crucible 11 in order to maintain the shape of the quartz crucible 11 that has been softened by heating. The quartz crucible 11 and the graphite crucible 12 constitute a double-structured crucible that supports the silicon melt 2 within the chamber 10.

The graphite crucible 12 is fixed to the upper end of the rotary shaft 13, and the lower end of the rotary shaft 13 passes through the bottom of the chamber 10 and is connected to the crucible drive mechanism 14 provided outside the chamber 10. The graphite crucible 12, rotary shaft 13, and crucible drive mechanism 14 constitute a crucible drive means for rotating the quartz crucible 11 and driving the same up and down. The rotation and vertical movement of the quartz crucible 11 driven by the crucible drive mechanism 14 are controlled by the controller 22.

The heater 15 is used to melt a silicon raw material charged in the quartz crucible 11 to produce the silicon melt 2, and to maintain the melted state of the silicon melt 2. The heater 15 is a resistance heating type heater made of carbon and is provided so as to surround the quartz crucible 11 within the graphite crucible 12. Further, a heat insulator 16 is provided outside the heater 15 so as to surround the heater 15, thereby improving heat retention within the chamber 10. The output of the heater 15 is controlled by the controller 22.

The heat-shield body 17 suppresses a temperature variation of the silicon melt 2 to provide appropriate heat distribution near the crystal growth interface and also prevents the silicon single crystal 3 from being heated by radiant heat from heater 15 and quartz crucible 11. The heat-shield body 17 is a substantially cylindrical member made of graphite and is provided so as to cover the area above the silicon melt 2 except for a pulling path for the silicon single crystal 3.

The diameter of an opening 17a at the lower end of the heat-shield body 17 is larger than the diameter of the silicon single crystal 3, thereby ensuring a pulling path for the silicon single crystal 3. Further, the outer diameter of the lower end of the heat-shield body 17 is smaller than the aperture of the quartz crucible 11, and the lower end of the heat-shield body 17 is located inside the quartz crucible 11, so that even when the upper end of the quartz crucible 11 is lifted above the lower end of the heat-shield body 17, the heat-shield body 17 does not interfere with the quartz crucible 11.

Although the amount of melt in the quartz crucible 11 decreases as the silicon single crystal 3 grows, the quartz crucible 11 is lifted so that the distance between the melt surface 2a and the heat-shield body 17 (gap value h_{G}) remains constant. By doing so, a temperature variation of the silicon melt 2 is suppressed, and the flow rate of the gas flowing near the melt surface 2a is kept constant, thereby controlling the amount of evaporation of a dopant from the silicon melt 2. Such gap control can improve stability of crystal defect distribution, oxygen concentration distribution, resistivity distribution, etc., in the pulling axis direction of the silicon single crystal 3.

Above the quartz crucible 11, there are provided the wire 18 serving as a pulling shaft for the silicon single crystal 3 and the crystal pulling mechanism 19 for pulling up the silicon single crystal 3 by winding the wire 18. These constitute a crystal pulling means for pulling up the silicon single crystal 3. The crystal pulling mechanism 19 has a function of rotating the silicon single crystal 3 together with the wire 18. The crystal pulling mechanism 19 is controlled by the controller 22. The crystal pulling mechanism 19 is arranged above the pull chamber 10b, and the wire 18 extends downward from the crystal pulling mechanism 19 through the inside of the pull chamber 10b, and the tip of the wire 18 reaches the internal space of the main chamber 10a. FIG. 1 illustrates a state where the silicon single crystal 3 being grown is suspended by the wire 18. Upon pulling of the silicon single crystal 3, the wire 18 is gradually pulled up while the quartz crucible 11 and silicon single crystal 3 are being rotated to grow the silicon single crystal 3.

A camera 20 is installed outside the chamber 10. The camera 20 is, for example, a CCD camera and photographs the inside of the chamber 10 through the viewing window 10e formed in the chamber 10. The camera 20 is installed at a predetermined angle with respect to the vertical direction and has a camera axis (optical axis) that is inclined with respect to the pulling axis of the silicon single crystal 3. That is, the camera 20 photographs the upper surface area of the quartz crucible 11 including the circular opening 17a of the heat-shield body 17 and the melt surface 2a of the silicon melt 2 from diagonally above.

The camera 20 is connected to the image processor 21, and the image processor 21 is connected to the controller 22. During the pulling process of the silicon single crystal 3, the image processor 21 calculates the crystal diameter near the solid-liquid interface from the contour pattern of the single crystal captured in the image photographed by the camera 20. The image processor 21 also calculates the distance from the heat-shield body 17 to the melt surface (gap value h_{G}) from the position of the mirror image of the heat-shield body 17 reflected on the melt surface in the image photographed by the camera 20.

The controller 22 controls a crystal diameter by controlling a crystal pulling speed based on data of the crystal diameter obtained from the image photographed by the camera 20. Specifically, when the measured value of the crystal diameter is larger than a target diameter, the crystal pulling speed is increased, and when it is smaller than the target diameter, the pulling speed is decreased. The controller 22 also controls the amount of movement of the quartz crucible 11 (crucible rising speed) based on the crystal length data of the silicon single crystal 3 obtained from the sensor output of the crystal pulling mechanism 19 and the gap value h_{G} (liquid level) obtained from the image photographed by the camera 20 so as to adjust the gap value h_{G} to a predetermined value.

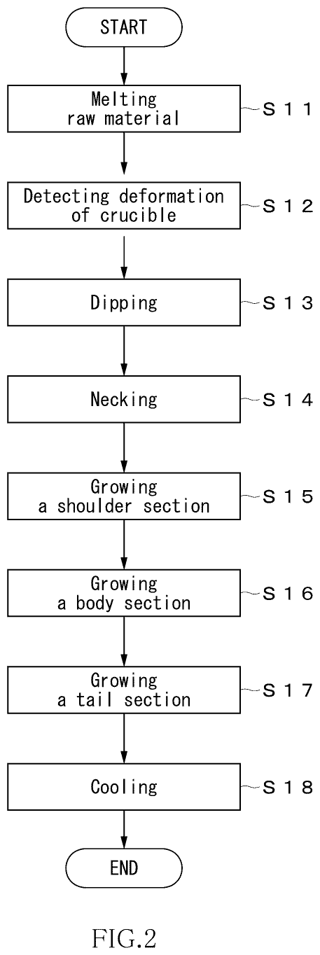

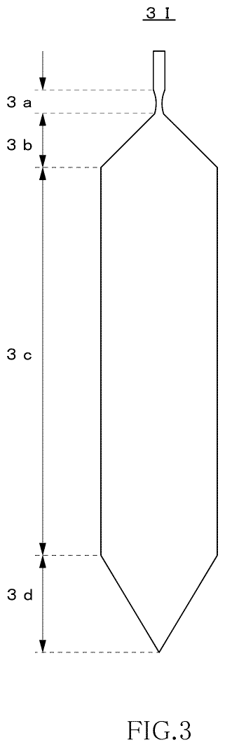

FIG. 2 is a flowchart illustrating a manufacturing process of the silicon single crystal according to the present embodiment. FIG. 3 is a schematic cross-sectional view illustrating the shape of a silicon single crystal ingot.

As illustrated in FIG. 2, the silicon single crystal manufacturing process according to the present embodiment includes a raw material melting step S11 in which a silicon raw material in the quartz crucible 11 is heated with the heater 15 to produce the silicon melt 2, a crucible deformation detection step S12 in which the presence/absence or magnitude of deformation of the quartz crucible 11 due to the influence of the raw material melting step S11 is evaluated, a dipping step S13 in which a seed crystal attached to the tip of the wire 18 is lowered to be dipped into the silicon melt 2, and a crystal growing step (S14 to S17) in which the seed crystal is gradually pulled up while a contact state with the silicon melt 2 is maintained to grow a single crystal.

As illustrated in FIGS. 2 and 3, the crystal growing step sequentially includes a necking step S14 of forming a neck section 3a whose crystal diameter is narrowed so as to avoid dislocation, a shoulder section growing step S15 of forming a shoulder section 3b whose crystal diameter is gradually increased as the crystal grows, a body section growing step S16 of forming a body section 3c whose crystal diameter is kept at a prescribed value, and a tail section growing step S17 of forming a tail section 3d whose crystal diameter is gradually reduced as the crystal grows.

Thereafter, a cooling step S18 is performed, in which the silicon single crystal 3 is separated from the melt surface 2a and cooled. Through the above steps, a silicon single crystal ingot 3I having the neck section 3a, shoulder section 3b, body section 3c, and tail section 3d as illustrated in FIG. 3 is completed. A silicon wafer according to the present invention is manufactured by sequentially performing steps such as peripheral grinding, slicing, lapping, etching, double-sided polishing, single-sided polishing, and cleaning for the silicon single crystal ingot 3I.

In the present embodiment, the melt surface 2a of the silicon melt 2 in the quartz crucible 11 is photographed by the camera 20 between the raw material melting step S11 and the dipping step S13, and deformation of the quartz crucible 11 is detected from a change in the mirror image of the quartz crucible 11 captured in the image photographed by the camera 20 (crucible deformation detection step S12). The reason why the deformation of the quartz crucible 11 is detected between the raw material melting step S11 and the dipping step S13 is that, after the shoulder section growing step S15, it becomes difficult to capture the mirror image of the quartz crucible 11 reflected on the melt surface 2a due to the presence of the silicon single crystal 3. Another reason is that, if signs of large deformation of the quartz crucible 11 can be detected early, it is easy to judge whether to continue or stop the crystal pulling.

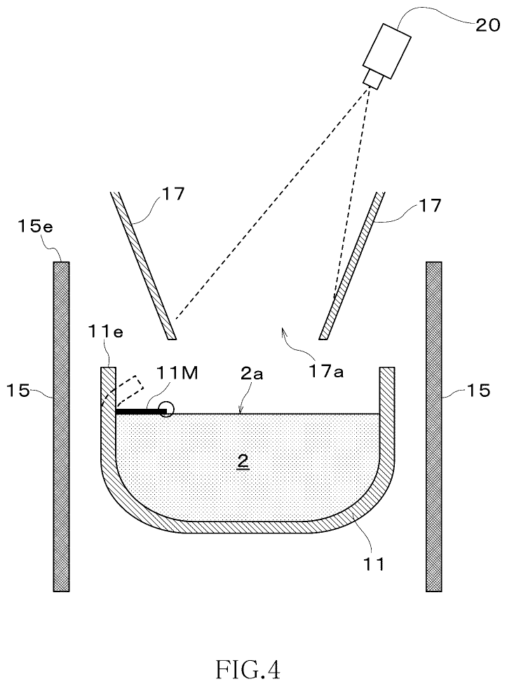

FIG. 4 is a view for explaining a method of detecting deformation of the quartz crucible 11, which is a conceptual view of a CZ pulling furnace in the raw material melting step S11.

As illustrated in FIG. 4, in the raw material melting step S11, the camera 20 photographs the melt surface 2a in order to detect deformation of the quartz crucible 11. The camera 20 can photograph the melt surface 2a of the silicon melt 2 that can be seen through the opening 17a of the heat-shield body 17. Since the heat-shield body 17 is present between the camera 20 and the quartz crucible 11, the camera 20 cannot directly capture the real image of the quartz crucible 11. A mirror image 11M of the quartz crucible 11 is reflected on the melt surface 2a; however, when an upper end 11e of the quartz crucible 11 falls inward, the position of the edge of the mirror image 11M of the quartz crucible 11 reflected on the melt surface 2a also changes. Therefore, the deformation of the quartz crucible 11 can be detected from the change in the mirror image 11M of the quartz crucible 11.

When the raw material melting step S11 is started, the solid silicon raw material is gradually melted, and the amount of silicon melt 2 increases. For a while after starting the raw material melting step S11, the amount of silicon melt 2 is small, and the solid raw material remains to some extent, so that the camera 20 cannot accurately capture the mirror image of the quartz crucible 11 reflected on the melt surface 2a. Further, since a large thermal load is yet to be applied to the quartz crucible 11, the quartz crucible 11 is not significantly deformed. When the melting of the raw material progresses to a certain extent, and the amount of silicon melt 2 in the quartz crucible 11 becomes sufficient, the mirror image edge of the upper end 11e of the quartz crucible 11 comes to be reflected on the melt surface 2a, thereby making it possible to detect deformation of the quartz crucible 11. When the amount of silicon melt 2 increases sufficiently, deformation of quartz crucible 11 due to the influence of thermal load becomes visible.

When the quartz crucible 11 is located at a relatively high position, and the distance (gap value h_{G}) from the lower end of the heat-shield body 17 to the melt surface 2a is small, the mirror image of the upper end 11e of the quartz crucible 11 is shielded by the heat-shield body 17, so that the mirror image edge cannot be observed. However, when the quartz crucible 11 is lowered sufficiently, the mirror image edge of the upper end 11e of the quartz crucible 11 can be placed within the field of view of the camera 20. Therefore, in the crucible deformation detection step S12, it is desirable to calculate the amount of deformation of the quartz crucible 11 by setting the melt surface 2a at a lower position than in the crystal growing step (particularly the body section growing step S16).

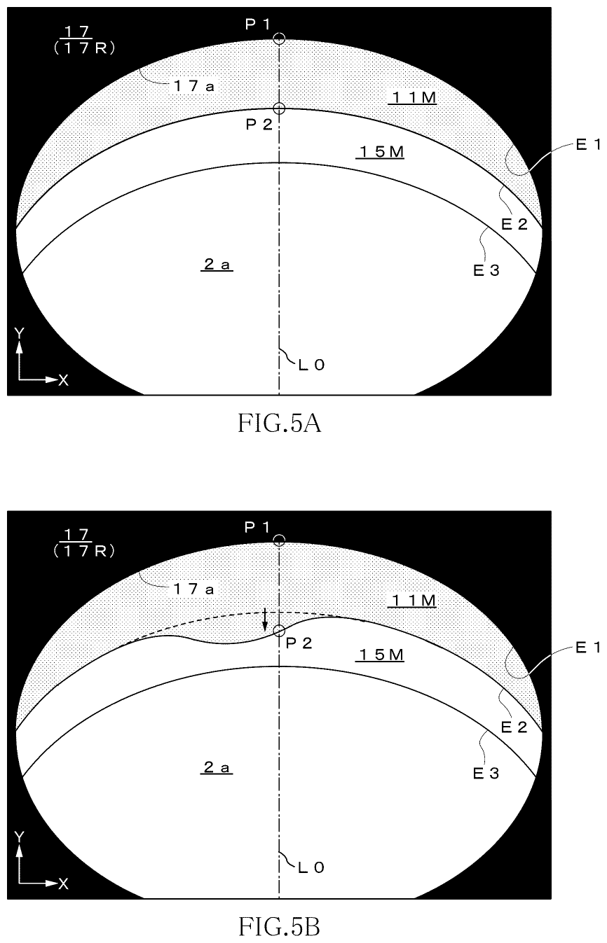

FIGS. 5A and 5B are schematic views of images of the melt surface 2a of the silicon melt 2 in the quartz crucible 11 photographed by the camera 20. FIG. 5A illustrates an image of the upper end of the quartz crucible 11 when the quartz crucible 11 is not deformed, and FIG. 5B illustrates an image of the upper end of the quartz crucible 11 when the quartz crucible 11 is deformed.

As illustrated in FIGS. 5A and 5B, the melt surface 2a of the silicon melt 2 in the quartz crucible 11 can be observed through the opening 17a of the heat-shield body 17 provided above the quartz crucible 11. In the image photographed by the camera 20, the black area is a real image 17R of the heat-shield body 17, and the entire area inside the opening 17a of the heat-shield body 17 is the melt surface 2a.

Since the melt surface 2a is a mirror surface, the upper end of the quartz crucible 11 and the upper end of the heater 15 are reflected on the melt surface 2a. In real space, the upper end of the heater 15 is located above the upper end of the quartz crucible 11, but the positional relation between the quartz crucible 11 and the heater 15 reflected on the melt surface 2a is upside down, and the lower part in the photographed image corresponds to the upper part of real space. Therefore, the mirror image edge of the quartz crucible 11 is located above the mirror image edge of the heater 15. The area between an arc-shaped edge line E1 of the heat-shield body 17 and an arc-shaped edge line E2 of the upper end of the quartz crucible 11 is a mirror image 11M of the quartz crucible 11, and the area between the arc-shaped edge line E2 of the upper end of the quartz crucible 11 and an arc-shaped edge line E3 of the upper end of the heater 15 is a mirror image 15M of the heater 15.

As illustrated in FIG. 5A, the edge line E2 of the mirror image 11M of the upper end 11e of the undeformed quartz crucible 11 has a beautiful arc shape. However, if the upper end 11e of the quartz crucible 11 falls inward as illustrated in FIG. 4, the arc shape of the mirror image 11M of the upper end 11e of the quartz crucible 11 changes as illustrated in FIG. 5B, and a part of the edge line E2 of the mirror image 11M moves downward in the vertical direction (Y-direction) of the image. The quartz crucible 11 is rotating at a constant speed, so that the position of the upper end of the quartz crucible 11 moves downward when viewed on a preset detection line L0. Therefore, by measuring a change in the position of an intersection P2 between the edge line E2 of the mirror image 15M of the quartz crucible 11 and the detection line L0 during one rotation of the quartz crucible 11, the amount of deformation of the upper end 11e of the quartz crucible 11 can be calculated.

It is preferable to set the detection line L0 within a plane including the optical axis of the camera 20. This allows the amount of deformation of the upper end 11e of the quartz crucible 11 to be easily calculated.

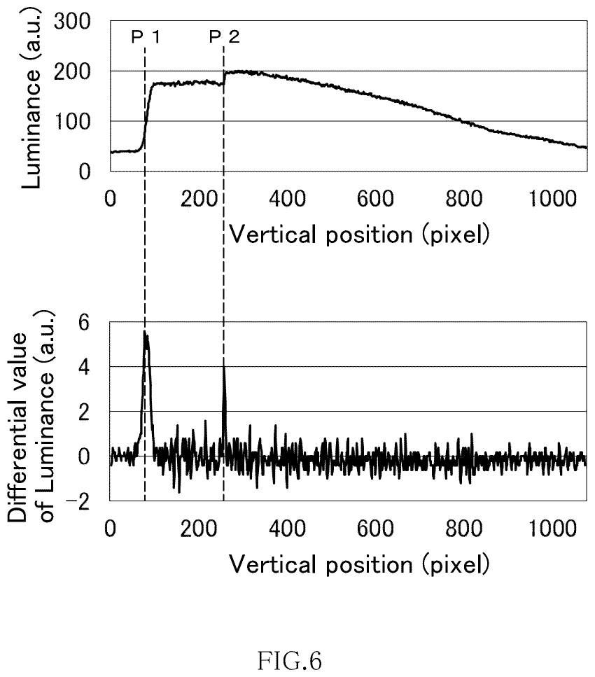

FIG. 6 is an explanatory view of how to determine the position of the mirror image edge of the quartz crucible 11.

As illustrated in FIG. 6, the position of the mirror image edge of the quartz crucible 11 on the detection line L0 can be determined from the differential value of luminance distribution in the vertical direction (Y-direction) of the photographed image. The vertical luminance distribution (the upper graph) of the photographed image reveals that the luminance changes greatly at a boundary position P1 between the real image 17R of the heat-shield body 17 and the mirror image 11M of the quartz crucible 11 (see FIGS. 5A and 5B) and also changes greatly at the boundary position P2 between the mirror image of the quartz crucible 11 and the mirror image of the heater 15.

When the differential value of the luminance distribution in the vertical direction (Y-direction) of the photographed image is calculated, two luminance peaks are obtained as shown in the lower graph. The position where the first peak luminance occurs corresponds to the position P1 of the lower end of the heat-shield body 17, and the position where the second peak luminance occurs corresponds to the position P2 of the mirror image edge of the quartz crucible 11. The position P2 of the mirror image edge at the upper end of the quartz crucible 11 thus obtained is measured at a predetermined imaging cycle (sampling cycle) during one rotation of the quartz crucible 11, and from the amount of change in the position P2 of the mirror image edge, the amount of deformation of the upper end 11e of the quartz crucible 11 can be determined.

An image photographing period (photographing interval) is preferably an angular pitch that is not divisible by 360 degrees. For example, integer values other than divisors of 360, such as 7 degrees and 11 degrees, can be listed. When measuring with an angular pitch that is divisible by 360 degrees, data of the same angle are piled up in the second and subsequent rotations of the crucible, making it impossible to fill in the gaps between the angular pitches. On the other hand, when measuring with an angular pitch that is not divisible by 360 degrees, such as a 7-degree pitch, the angle fills the gap that is a multiple of 7 in the second or subsequent rotations, with the result that data for 1-degree pitch can be obtained every 7 rotations. Further, the shorter the photographing period, the more accurate the measurement of the amount of deformation of the upper end 11e of the quartz crucible 11 can be, but the burden of image processing increases. Therefore, the lower limit value of the image photographing period may be determined depending on the crucible rotation speed and capability of the image processing device. For example, the photographing period can be set to 0.5 degrees or more. Further, the upper limit of the image photographing period can be set to, for example, 15 degrees or less, or 10 degrees or less.

As described above, the amount of deformation of the upper end 11e of the quartz crucible 11 is determined from the deviation of the vertical position of the mirror image edge during one rotation of the quartz crucible 11, so when the crucible falls inward over the entire circumference, it is impossible to determine the amount of deformation correctly. However, as illustrated in FIG. 5B, the inward falling of the quartz crucible 11 occurs locally and rarely occurs over the entire circumference of the crucible. Therefore, even with the above method, it is possible to accurately determine the amount of deformation of the crucible. Furthermore, when the pixel position when the crucible is not deformed is determined in advance as a reference value, it is possible to determine the amount of deformation correctly even when the entire circumference of the crucible falls inward.

In order to eliminate measurement errors and accurately determine the amount of deformation of the upper end 11e of the quartz crucible 11, it is preferable to determine the average value of a plurality of measured values. To this end, it is preferable to obtain N measurement results of the amount of deformation of the quartz crucible 11 from a plurality of images photographed while the quartz crucible 11 rotates N times continuously and to obtain the average value of these N measurement results.

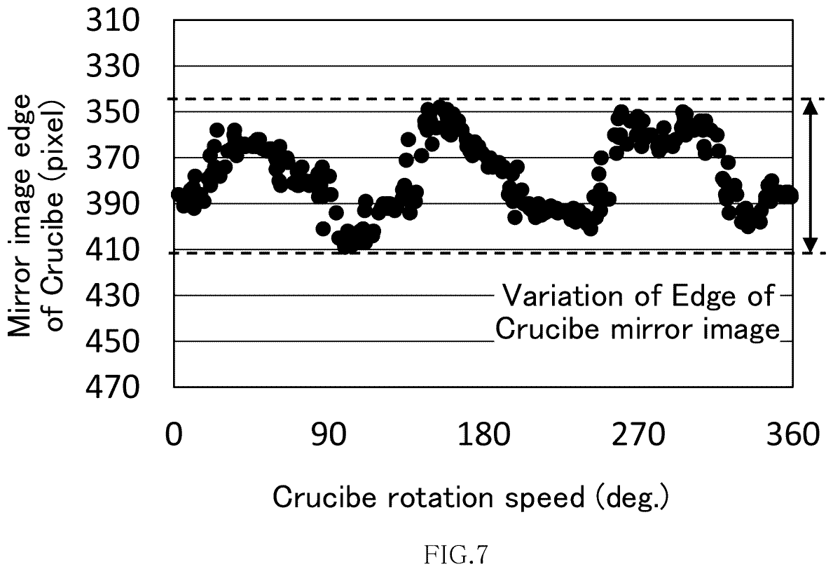

FIG. 7 is a graph illustrating an example of the measurement results of the position of the mirror image edge at the upper end of the quartz crucible 11 rotating at a constant speed. In this graph, the horizontal axis represents a crucible rotation angle (degree), and the vertical axis represents the pixel position (pixel) of the mirror image edge of the quartz crucible.

As illustrated in FIG. 7, the position of the mirror image edge of the quartz crucible 11 in the Y-direction fluctuates in the vertical direction during one rotation of the quartz crucible 11, and it can be seen that the mirror image edge position becomes maximum at positions of approximately 30°, 150°, and 270°, while it becomes minimum at positions of approximately 110°, 220°, and 330°. It can also be seen that the maximum amount of change in the vertical direction of the crucible mirror image edge is approximately 60 pixels. In this way, the amount of deformation of the quartz crucible 11 can be determined from a change in the mirror image of the quartz crucible 11.

The amount of deformation of the quartz crucible 11 determined from the above photographed image is the number of pixels (pixels), and in order to convert this into the amount of deformation (millimeter) in real space, unit conversion is required. The unit conversion method is not particularly limited, but for example, the actual deformation amount can be determined from the correspondence between the number of moving pixels per unit time when a point at the upper end of the quartz crucible 11 moves in association with crucible rotation and the actual travel distance per unit time determined from the diameter and rotation speed of the quartz crucible 11. That is, assume that a point on the mirror image edge of the quartz crucible 11 is moving from a certain coordinate point A to another coordinate point B. On the other hand, the moving distance of one point at the upper end of the quartz crucible 11 in real space can be determined from the diameter and rotation speed of the quartz crucible, so that the moving distance in real space per pixel can be determined by making the number of pixels between A and B in the photographed image and the moving distance in real space correspond to each other.

As a result of measuring the amount of deformation of the quartz crucible 11 described above, when the amount of deformation exceeds a threshold value, the controller 22 may output a warning with sound or screen display. This makes it possible to draw operator's attention.

As described above, in the silicon single crystal manufacturing method according to the present embodiment, the melt surface 2a of the silicon melt 2 in the quartz crucible 11, which can be seen through the opening 17a of the heat-shield body 17, is captured by the camera 20, and the amount of deformation of the quartz crucible 11 is calculated from a temporal change in the mirror image 11M of the quartz crucible 11 reflected on the melt surface 2a. Thus, the probability of an accident due to deformation of the quartz crucible 11 can be predicted and prevented. Further, by feeding back the influence of the crystal pulling conditions on the deformation of the quartz crucible 11, deformation of the crucible can be prevented.

Further, the silicon single crystal manufacturing apparatus according to the present embodiment includes the camera 20 for photographing, from diagonally above, the melt surface 2a of the silicon melt 2 in the quartz crucible 11 which can be seen through the opening 17a of the heat-shield body 17 and the image processor 21 that processes the image photographed by the camera 20. The camera 20 acquires a plurality of images including the mirror images of the quartz crucible 11 reflected on the melt surface 2a of the silicon melt 2 at predetermined time intervals while the quartz crucible 11 rotates at least once, and the image processor 21 calculates the amount of deformation of the quartz crucible 11 from a temporal change in the mirror image 11M of the quartz crucible 11 captured in each of the plurality of images. Thus, the probability of an accident due to deformation of the quartz crucible 11 can be predicted and prevented. Further, by feeding back the influence of the crystal pulling conditions on the deformation of the quartz crucible 11, deformation of the crucible can be prevented.

While the preferred embodiment of the present invention has been described, the present invention is not limited to the above embodiment, and various modifications may be made within the scope of the present invention, and all such modifications are included in the present invention.

For example, in the above embodiment, a case has been described in which the amount of deformation due to the inward falling of the upper end 11e of the quartz crucible 11 is calculated; however, the present invention is not limited to calculation of such deformation but can also be applied to a case where the circumferential height of the upper end 11e varies due to the sinking of the quartz crucible 11. Further, it is also possible to employ the present invention as a method of calculating the amount of eccentricity in a case where the central axis of the quartz crucible 11 deviates from the central axis of rotation and rotates eccentrically. In this case, the amount of eccentricity of the quartz crucible 11 can be calculated from the periodic deviation of the position of the mirror image edge that is synchronized with the rotation period of the crucible.

Further, in the above embodiment, the amount of deformation of the quartz crucible 11 is calculated by photographing the mirror image of the quartz crucible 11 during a period from the raw material melting step S11 until the start of the dipping step S13; however, the timing for measuring the amount of deformation of quartz crucible 11 is not limited to the above period, but the measurement can be performed at a desired timing when the mirror image edge of the quartz crucible 11 reflected on the melt surface 2a can be photographed. Further, when the mirror image of the quartz crucible 11 can be photographed during crystal pulling, it is also possible to continuously detect the amount of deformation of the quartz crucible 11.

Further, the detection of the amount of deformation of the quartz crucible according to the present invention can also be applied to a so-called multi-pulling method. In the multi-pulling method, after pulling a silicon single crystal, silicon raw materials are additionally supplied and melted in the same quartz crucible, and a silicon single crystal is pulled from the obtained silicon melt. The above raw material supply process and single crystal pulling process are repeated to manufacture a plurality of silicon single crystals from a single quartz crucible. In the process of melting the additionally supplied raw material, by employing the method of calculating the amount of crucible deformation according to the present invention, it is possible to objectively judge whether or not it is possible to continue the multi-pulling method.

Further, in the above embodiment, an image for detecting the amount of deformation of the quartz crucible 11 is acquired using the camera 20 for use in measurement of the crystal diameter and gap value; however, the present invention is not limited to such a configuration, but an image of the melt surface 2a may be photographed using a dedicated camera different from the camera used for diameter measurement or the like.

### DESCRIPTION OF REFERENCE NUMERALS

1 single crystal manufacturing apparatus
2 silicon melt
2a melt surface
3 silicon single crystal
3I silicon single crystal ingot
3 a neck section
3b shoulder section
3c body section
3d tail section
10 chamber
10a main chamber
10b pull chamber
10c gas inlet
10d gas exhaust port
10e viewing window
11 quartz crucible
11M mirror image of quartz crucible
12 graphite crucible
13 rotary shaft
14 crucible drive mechanism
15 heater
15M mirror image of heater
16 heat insulator
17 heat-shield body
17R real image of heat-shield body
17a opening of heat-shield body
18 pulling wire
19 crystal pulling mechanism
20 camera
21 image processor
22 controller
E1 edge line of real image of heat-shield body
E2 edge line of mirror image of quartz crucible
E3 edge line of mirror image of heater
L0 detection line
S11 raw material melting step
S12 crucible deformation detection step
S13 dipping step
S14 necking step
S15 shoulder section growing step
S16 body section growing step
S17 tail section growing step
S18 cooling step

1. A silicon single crystal manufacturing method for manufacturing a silicon single crystal by pulling a silicon single crystal from a silicon melt in a quartz crucible, comprising:
acquiring images including a mirror image of the quartz crucible reflected on a melt surface of the silicon melt at predetermined time intervals; and
evaluating deformation or eccentricity of the quartz crucible from a temporal change in the position of the mirror image of the quartz crucible captured in a plurality of images acquired while the quartz crucible rotates at least once.

2. The silicon single crystal manufacturing method according to claim 1, wherein
a position of an upper end of the quartz crucible is detected from the mirror image of the quartz crucible, and
an amount of deformation or eccentricity of the upper end is calculated from a temporal change in the position of the upper end.

3. The silicon single crystal manufacturing method according to claim 2, wherein
the upper end of the quartz crucible is detected from the differential value of luminance in the vertical direction of pixels in the image.

4. The silicon single crystal manufacturing method according to claim 1, further including:
setting a detection line for the position of the upper end in a plane including the optical axis of a camera for photographing the image; and
calculating a change amount of the quartz crucible from the temporal change in the position of the mirror image of the quartz crucible on the detection line.

5. The silicon single crystal manufacturing method according to claim 1, further including:
calculating a change amount of the quartz crucible based on the plurality of images acquired during a period from the start of a raw material melting step of melting a silicon raw material in the quartz crucible until the start of a dipping step of dipping a seed crystal into the silicon melt.

6. A silicon single crystal manufacturing apparatus comprising:
a quartz crucible that holds a silicon melt;
a heater that is provided so as to surround the quartz crucible and heats the silicon melt;
a crucible driving unit that rotates the quartz crucible and drives the same up and down;
a crystal pulling unit that pulls up a silicon single crystal from the silicon melt;
a heat-shield body that is disposed above the quartz crucible so as to surround the silicon single crystal pulled up from the silicon melt;
a camera that photographs a melt surface of the silicon melt that can be seen through an opening of the heat-shield body from diagonally above; and
an image processor that processes images photographed by the camera, wherein
the camera acquires images including a mirror image of the quartz crucible reflected on the melt surface at predetermined time intervals, and
the image processor evaluates deformation or eccentricity of the quartz crucible from a temporal change in the position of the mirror image of the quartz crucible captured in a plurality of images acquired while the quartz crucible rotates at least once.

7. The silicon single crystal manufacturing apparatus according to claim 6, wherein the image processor detects a position of an upper end of the quartz crucible from the mirror image of the quartz crucible and calculates an amount of deformation or eccentricity of the upper end from a temporal change in the position of the upper end.

8. The silicon single crystal manufacturing apparatus according to claim 7, wherein, the image processor detects the upper end of the quartz crucible from the differential value of luminance in the vertical direction of pixels in the image.

9. The silicon single crystal manufacturing apparatus according to claim 6, wherein the image processor sets a detection line for the position of the upper end in a plane including the optical axis of the camera for photographing the image and calculates a charge amount of the quartz crucible from the temporal change in the position of the mirror image of the quartz crucible on the detection line.

10. The silicon single crystal manufacturing apparatus according claim 6, wherein the image processor calculates a change amount of the quartz crucible based on the plurality of images acquired during a period from the start of a raw material melting step of melting a silicon raw material in the quartz crucible until the start of a dipping step of dipping a seed crystal into the silicon melt.

11. A silicon wafer manufacturing method comprising:
producing a silicon wafer by processing a silicon single crystal manufactured by the above-described silicon single crystal manufacturing method according to claim 1.
